(19) United States
(12) Patent Application Publication
(10) Pub. No.: US 2005/0155551 A1
(43) Pub. Date: Jul. 21, 2005

(54) Deposition apparatus and related methods including a pulse fluid supplier having a buffer

(76) Inventors: Byoung-Jae Bae, Gyeonggi-do (KR); Young-Bae Choi, Gyeonggi-do (KR); Ji-Eun Lim, Seoul (KR)

Correspondence Address: Laura M. Kelley;Myers Bigel Sibley & Sajovec, P.A., P. O. Box 37428, Raleigh, NC, 27627, US

(21) Appl. No.: 10/952,323

(22) Filed: Sep. 28, 2004

(30) Foreign Application Priority Data
Jan. 19, 2004 (KR) 2004-03925

(51) Int. Cl. C23C 16/00

(52) U.S. Cl. 118/715; 427/248.1

(57) ABSTRACT

A deposition apparatus for depositing a predetermined material on a semiconductor substrate includes a chamber configured to perform a deposition process and a source gas supplier having a pulse fluid supplier configured to cyclically supply a source of a source gas to the chamber. The pulse fluid supplier includes a buffer configured to provide a space in which a fluid is received and a body including a first supply port connected to a source supplier, a second supply port connected to a carrier gas supply pipe, and a discharge port connected to a fluid supply pipe. The fluid supply pipe is configured such that fluid in the buffer flows through the fluid supply pipe to the chamber. The pulse fluid supplier includes a controller configured to selectively allow or prevent a source fluid supplied by the first supply port and a carrier gas supplied by the second supply port to flow to/from the buffer, and to allow or prevent a fluid in the buffer to flow to/from the fluid supply pipe.

This application claims priority from Korean Patent Application No. 2004-03925, filed on Jan. 19, 2004, the contents of which are herein incorporated by reference in their entirety.

### FIELD OF THE INVENTION

The present invention generally relates to apparatus and methods for fabricating semiconductor devices and, more specifically, to apparatus and methods for depositing a material on a substrate.

### BACKGROUND OF THE INVENTION

Deposition processes can be used to deposit predetermined materials on various substrates, such as on wafers to fabricate semiconductor devices. Examples of deposition methods include chemical vapor deposition (CVD) methods and physical vapor deposition (PVD) methods. Compared with the PVD method, the CVD method may provide a lower cost, reduced damages to substrates and/or simultaneous processing with respect to a plurality of substrates.

In addition, CVD processes may include general chemical vapor deposition (CVD) processes or atomic layer vapor deposition (ALD) processes. The general CVD process may be performed by continuously and simultaneously providing source gases to a deposition chamber. The ALD process may be performed by sequentially providing a first source gas, a purge gas, a second source gas and a purge gas. There are advantages in the ALD process as compared with the general CVD process. For example, a film having a regular thickness can be obtained on wafers at a relatively low temperature, and reaction by-products, which may include contaminants, may be easily removed.

Cyclic chemical vapor deposition processes have also been used to deposit a material on a substrate. In the cyclic chemical vapor deposition process, a first source gas is cyclically provided to a process chamber utilizing time division, and a second source gas is continuously provided to a chamber. While the first source gas is not supplied, reaction by-products on the wafer may be removed, and the wafer can be thermally annealed due to the second source gas. FIGS. 1A to 1C, respectively, show methods for providing process gases by a general chemical vapor deposition method, a cyclic chemical vapor deposition method and an atomic vapor deposition method.

While performing the cyclic chemical vapor deposition method or the atomic layer deposition method, whether the source gases are provided or not is controlled by a mass flow controller. However, when the source gases are cyclically provided using the mass flow controller, the fluctuation of the supply flow rate of the source gas may vary during the cycle, which can adversely affect the deposition of the material. A fluctuating supply flow rate may increase when the supply cycle is short. As a result, it may be difficult for source gases to be provided at a regular flow rate. In particular, if a source of the source gas which flows into the mass flow controller is liquid, the fluctuation of the flow rate may be large and may adversely affect the deposition of the material.

### SUMMARY OF THE INVENTION

According to embodiments of the present invention, a deposition apparatus for depositing a predetermined material on a semiconductor substrate includes a chamber configured to perform a deposition process and a source gas supplier having a pulse fluid supplier configured to cyclically supply a source of a source gas to the chamber. The pulse fluid supplier includes a buffer configured to provide a space in which a fluid is received and a body including a first supply port connected to a source supplier, a second supply port connected to a carrier gas supply pipe, and a discharge port connected to a fluid supply pipe. The fluid supply pipe is configured such that fluid in the buffer flows through the fluid supply pipe to the chamber. The pulse fluid supplier includes a controller configured to selectively allow or prevent a source fluid supplied by the first supply port and a carrier gas supplied by the second supply port to flow to/from the buffer, and to allow or prevent a fluid in the buffer to flow to/from the fluid supply pipe.

According to some embodiments of the present invention, a pulse fluid supplier includes a buffer configured to provide a space in which a fluid is received and a body including a first supply port configured to connect to a source supplier, a second supply port configured to connect to a carrier gas supply pipe, and a discharge port configured to connect to a fluid supply pipe such that fluid in the buffer flows through the fluid supply pipe to a deposition chamber. A controller is configured to selectively allow or prevent a source fluid supplied by the first supply port and a carrier gas supplied by the second supply port to flow to/from the buffer, and to allow or prevent a fluid in the buffer to flow to/from the fluid supply pipe.

According to some embodiments of the invention, methods for performing a deposition process include opening a passage between a source supply and a buffer to fill the buffer with a source fluid. The passage between the source supply and the buffer is closed, and while the passage between the source supply and the buffer is closed, a passage between a carrier gas supply and the buffer and a passage between the buffer and a deposition chamber are opened to supply the deposition chamber with the source fluid.

In some embodiments according to the present invention, methods for performing a deposition process include opening a passage between a first source supply and a first buffer to fill the first buffer with a first source fluid. The passage between the first source supply and the first buffer is closed, and while the passage between the first source supply and the first buffer is closed, a passage between a first carrier gas supply and the first buffer and a passage between the first buffer and a deposition chamber is opened to supply the deposition chamber with the first source fluid. While the passage between the first source supply and the first buffer is closed and the first source fluid is supplied to the deposition chamber, a passage between a second source supply and a second buffer is opened to fill the second buffer with a second source fluid. The passage between the second source supply and the second buffer is closed, and while the passage between the second source supply and the second buffer is closed, a passage between a second carrier gas supply and the second buffer and a passage between the second buffer and a deposition chamber are opened to supply the deposition chamber with the second source fluid.

According to further embodiments of the present invention, methods for performing a deposition process by supplying a first source gas and a second source gas to a chamber are provided. A pulse fluid supplier is provided that includes a first connection port that provides an inlet to a buffer, a second connection port that provides an outlet from the buffer, a first supply port that receives a source fluid from a source supplier, a second supply port that receives a carrier gas from a carrier gas supplier, and a discharge port that provides fluid to a deposition chamber. A passage connecting the first connection portion and the first supply port, a passage connecting the first connection port and the second supply port, and a passage connecting the second connection port and the discharge port are provided. The passage that connects the first connection port and the first supply port is opened to charge the buffer with the source fluid while the passage that connects the second supply port to the carrier gas supplier and the passage that connects the second connection port and the discharge port are closed. The passage that connects the first connection port and the second supply port and the passage that connects the second connection port and the discharge port are opened to discharge the buffer and supply the source fluid to the deposition chamber while the passage that connects the first connection port and the first supply port is closed.

According to further embodiments of the present invention, methods for performing a deposition process by supplying a first source gas and a second source gas to a chamber are provided. A first pulse fluid supplier connected to a first source fluid and a second pulse fluid supplier connected to a second source fluid are provided. Each of the pulse fluid suppliers include a first connection port that provides an inlet to a buffer, a second connection port that provides an outlet from the buffer, a first supply port that receives the first source fluid or the second source fluid from a respective first source supplier or second source supplier, a second supply port that receives a carrier gas from a carrier gas supplier, and a discharge port that provides fluid to a deposition chamber. A passage connecting the first connection portion and the first supply port in the first and the second pulse fluid supplier, a passage connecting the first connection port and the second supply port in the first and the second pulse fluid supplier, and a passage connecting the second connection port and the discharge port in the first and the second pulse fluid are provided. The first pulse fluid supplier is discharged to supply the first source gas to the deposition chamber while the second pulse fluid supplier is charged. A purge gas is supplied to the deposition chamber while the buffer of the first pulse fluid supplier is pumped. The second pulse fluid supplier is discharged to supply the second source gas to the deposition chamber while the first pulse fluid supplier is charged. The steps of charging the first or the second pulse fluid supplier include opening the passage that connects the first connection port and the first supply port to charge the buffer with the first or the second source fluid while closing the passage that connects the second supply port to the carrier gas supplier and the passage that connects the second connection port and the discharge port. The steps of discharging the first or the second pulse fluid supplier include opening the passage that connects the first connection port and the second supply port and the passage that connects the second connection port and the discharge port to discharge the buffer and supply the first or second source fluid to the deposition chamber while closing the passage that connects the first connection port and the first supply port.

### BRIEF DESCRIPTION OF THE DRAWINGS

FIGS. 1A to 1C are timing diagrams illustrating methods for providing processing gases using various chemical vapor deposition (CVD) methods.

FIG. 2 is a schematic diagram illustrating a chemical vapor deposition apparatus according to a embodiments of the present invention.

FIG. 3 is a schematic diagram illustrating an apparatus according to further embodiments of the present invention.

FIG. 4 is a perspective view of a pulse fluid supplier according to embodiments of the present invention.

FIG. 5 is a schematic diagram of the pulse fluid supplier of FIG. 4.

FIG. 6 is a schematic diagram of a controller of the pulse fluid supplier of FIG. 4.

FIGS. 7A and 7B are schematic diagrams illustrating a passage that is opened by an actuator for connecting ports of the pulse fluid supplier of FIG. 4.

FIG. 8 is a timing diagram illustrating processes of the pulse fluid supplier of FIG. 4.

FIGS. 9 to 11 are schematic diagrams of the passages that connect the ports of the pulse fluid supplier of FIG. 4 illustrating a fluid flow that is opened or blocked in a charge step, a discharge step and a pumping step, respectively.

FIG. 12 is a flowchart illustrating operations of a deposition process by a cyclic chemical vapor deposition method using the apparatus of FIG. 1 according to embodiments of the present invention.

FIG. 13 is a schematic diagram of an apparatus for performing a deposition process by an atomic layer deposition method using the pulse fluid supplier of FIG. 4.

FIG. 14 is a flowchart illustrating operations of a deposition process using the atomic layer deposition method according to embodiments of the present invention.

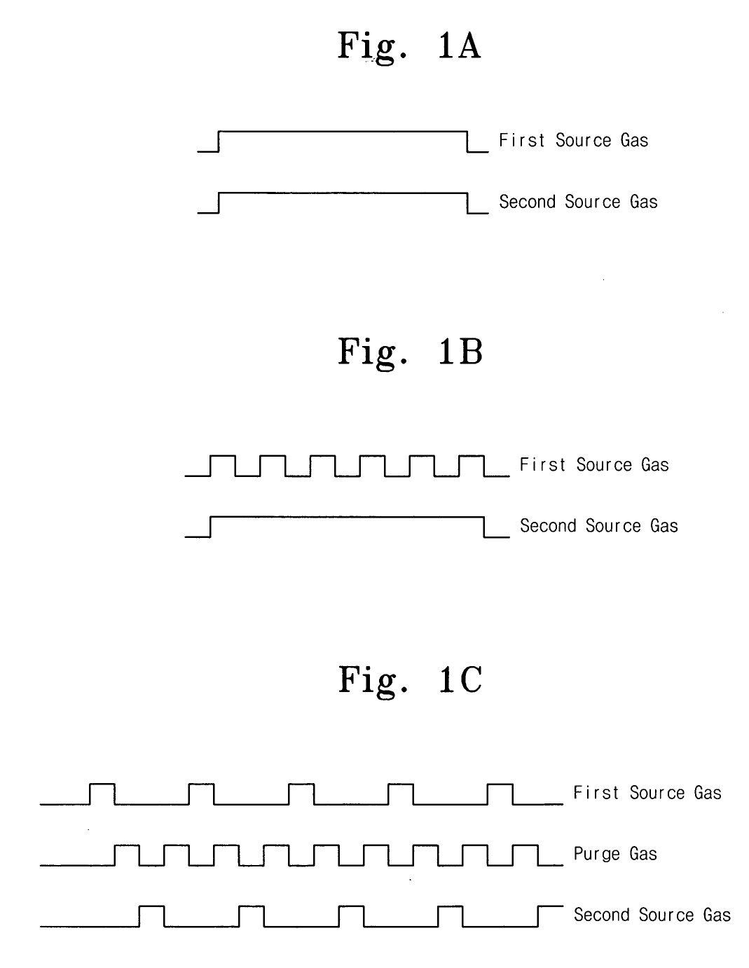

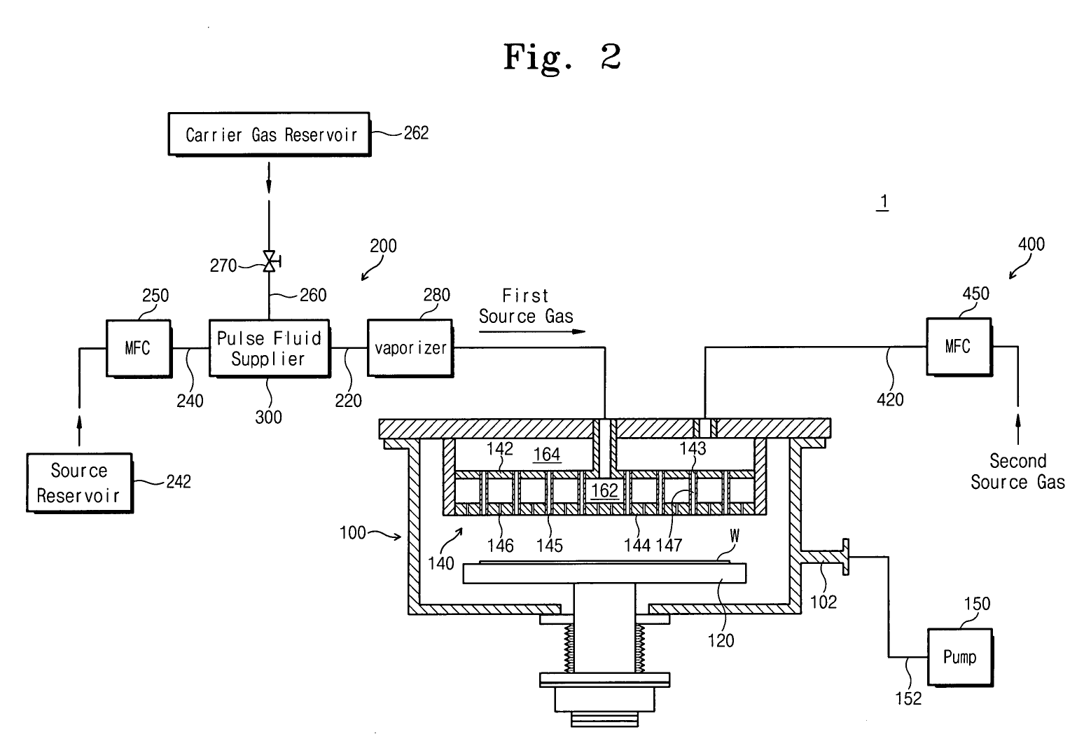

### DETAILED DESCRIPTION OF THE PREFERRED EMBODIMENT

The present invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. As used herein, “connect” means that the referenced elements are either directly or indirectly connected, i.e., that the referenced elements may be attached either to each other or by way of one or more common intermediate elements. Like numbers refer to like elements throughout the specification.

It should be understood that the present invention is not limited to the particular embodiments illustrated, and other suitable apparatus or methods may be used in which materials are deposited on a substrate, including methods and apparatuses for atomic layer deposition method and/or chemical vapor deposition. In addition, as used herein, a “source” refers to any suitable source that can be used to provide a quantity of the source material as a gas. A gas source may be gaseous or liquid.

FIG. 2 illustrates a deposition apparatus 1 for depositing an organic metal on a substrate in which a cyclic chemical vapor deposition method is used according to embodiments of the present invention. Referring to FIG. 2, the deposition apparatus 1 includes a chamber 100, a first source gas supply part 200 and a second source gas supply part 400.

The chamber 100 receives a substrate such as a wafer W and provides a space where the deposition process is performed. A substrate support 120 on which the wafer is placed and an injection part 140 are installed. The substrate support 120 is placed at a lower portion of the chamber 100. A heater (not shown) for heating the wafer W at a high temperature is installed in the substrate support 120 so that source gases may be uniformly deposited on the wafer W. The injection part 140 is placed on an upper portion of the chamber 100 opposite the substrate support 120. The injection part 140 may be a shower head. In this case, the shower head can be combined with the upper surface of the chamber 100 in order to inject source gases flowing into the chamber 100 downwards using a plurality of injection ports. An exhaust port 102 can be formed on one or more sides of the chamber 100, such as the bottom side of the chamber 100. An exhaust pipe 152 where a vacuum pump 150 is installed is connected to the exhaust port 102. A regular or substantially constant pressure may be maintained in the chamber by operating the vacuum pump 150. By-products caused by performing a process may be exhausted through the exhaust pipe 152.

The injection part 140 has a first inlet 162 and a second inlet 164. The first inlet 162 is positioned below the second inlet 164. A first injection plate 142 is located between the first inlet 162 and the second inlet 164 and separates the first inlet 162 from the second inlet 164. A second injection plate 144 is formed under the first inlet 162. A plurality of holes 143 are formed in the first injection plate 142, and holes 145 are formed in a position respectively corresponding to the first holes in the second injection plate 144. Holes 146 are formed between the holes 145. Injection pipes 147 are inserted in the holes 143 and 145 to provide a passage therebetween.

If an organic metal is deposited on the wafer W, a first source can have a low vapor pressure and can be a metal organic precursor gas that may be liquid or solid at room temperature. The first source can be supplied to the injection part 140 in a heated state at a suitable temperature, the selection of which is known to those of skill in the art. A second source gas may be gaseous at room temperature. If an oxide layer is deposited on the wafer W, the second source gas may be a gas such as O₂. If a nitride layer is deposited on the wafer W, the second source gas can be a gas such as N₂ or NH₃. In other words, if SiO₂ is being deposited on the wafer W, the first source gas can be TEOS (Tetra-Ethyl-Ortho-Silicate), and the second gas can be O₂. The first source gas may be cyclically provided from the first source gas supply part 200 to the first inlet 162, and the second source gas can be continuously provided from the second source gas supply part 400 to the second inlet 164.

Although the apparatus 1 is illustrated in FIG. 2 as including an injection part 140 that has more than one inlet (first inlet 162 and second inlet 164) and more than one injection part (first injection part 142 and second injection part 144), the apparatus may be modified to have only one inlet and one injection plate. Thus, the first and second source gases may be provided to the same inlet and are injected through holes formed on the injection plate under the inlet.

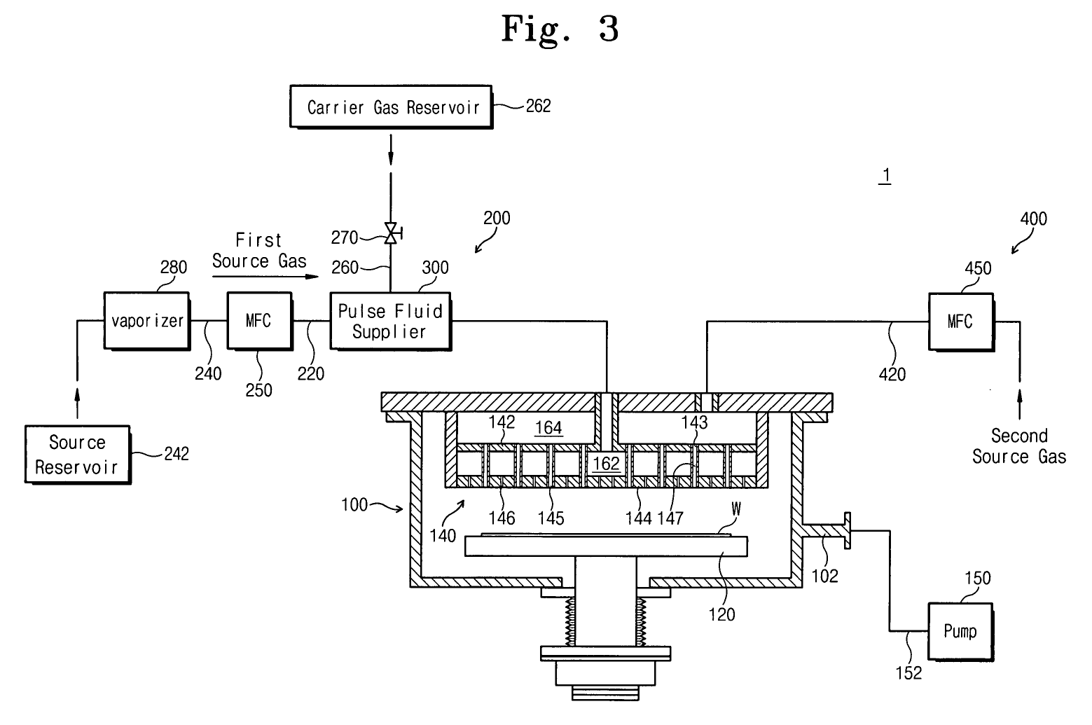

The first source gas supply part 200 has a vaporizer 280, a fluid supply pipe 220, a source supplier 240, a carrier gas supply pipe 260 and a pulse fluid supplier 300. The fluid supply pipe 220 is connected to the first inlet 162 to provide a passage for a fluid supplied from the pulse fluid supplier 300. The pulse fluid-supplier 300 cyclically provides a source of the first source gas by utilizing time division and is connected to the source supplier 240 and the carrier gas supply pipe 260. A mass flow controller (MFC) 250 is installed on the source supplier 240 connected to a source reservoir 242. A flow control valve 270 may be installed on the carrier gas supply pipe 260 and connected to a carrier gas reservoir 262. Nitrogen gas N₂ can be used as a carrier gas. As shown in FIG. 2, the vaporizer 280 vaporizes a liquid source and is installed on the fluid supply pipe 220. In some embodiments, the source is liquid and is supplied to the pulse fluid supplier 300. The liquid source cyclically supplied from the pulse fluid supplier 300 is vaporized in the vaporizer 280 and then is supplied to the chamber 100. As shown in FIG. 3, the vaporizer 280 may be installed on the source supplier 240, and a source in a gas state may be supplied to the pulse fluid supplier.

A second source gas supply part 400 provides a second source gas to the second inlet 164 and has a fluid supply pipe 420 where the mass flow controller 450 is installed. A fluid supply pipe 420 is connected to the second inlet 164.

When a source is provided from only mass flow controller 250 (e.g., the pulse fluid supplier 300 is omitted), the quantity of gas may be difficult to control. For example, particularly if a supply cycle is short, the flow rate can fluctuate, and the deposition process may be adversely affected. As a result, the quantity of the source may vary. According to embodiments of the present invention, the pulse fluid supplier 300 can cyclically provide a source having a substantially regular quantity.

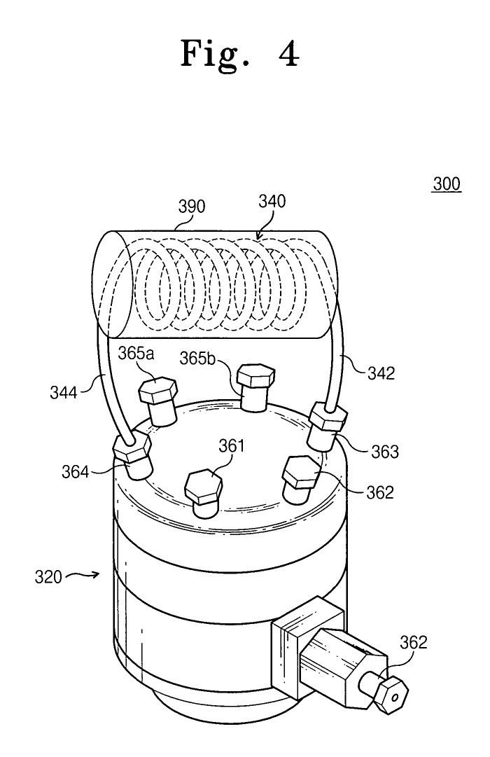

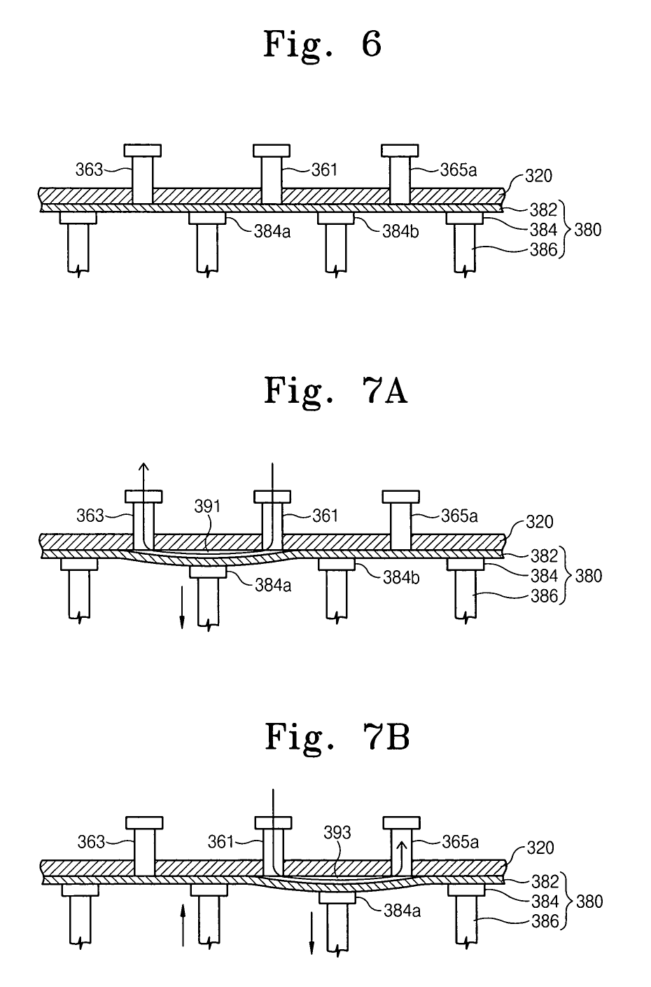

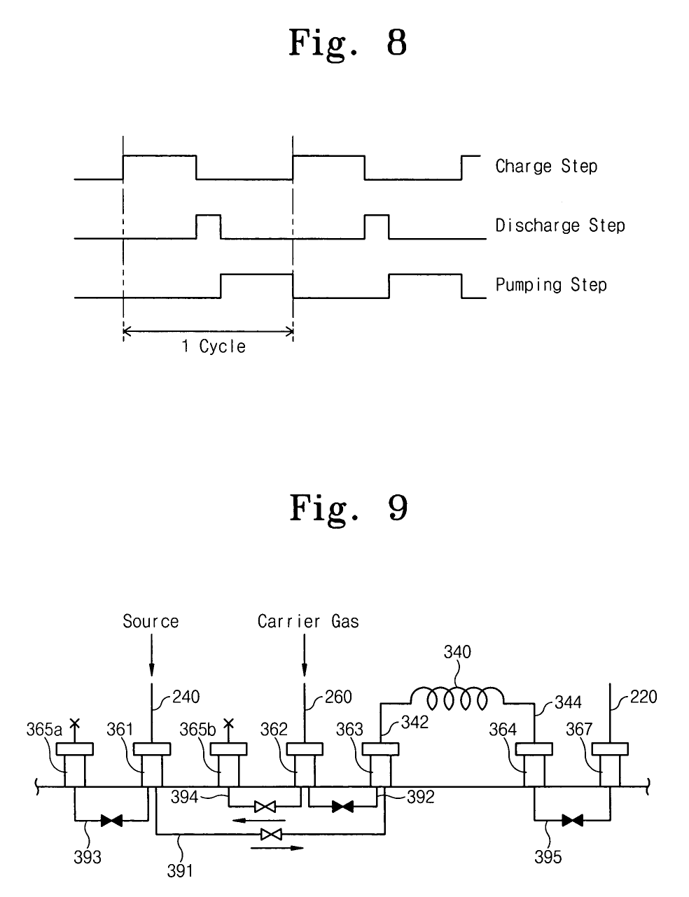

Referring to FIGS. 4-6, 7A-7B and 9, the pulse fluid supplier 300 has a body 320, a buffer 340, a controller 380 (shown in FIG. 6), and a temperature regulator 390. A plurality of ports 361, 362, 363, 364, 365 and 367 are connected to external pipes 220, 240, 260, 342 and 344 and are formed in the body 320 of the pulse fluid supplier. It should be understood that the ports 361, 363 and 365a shown in FIGS. 6, 7A and 7B are placed in a plane as shown in FIG. 4. However, for ease of representation, the ports 361, 363 and 365a are shown in a straight line in FIGS. 6, 7A and 7B.

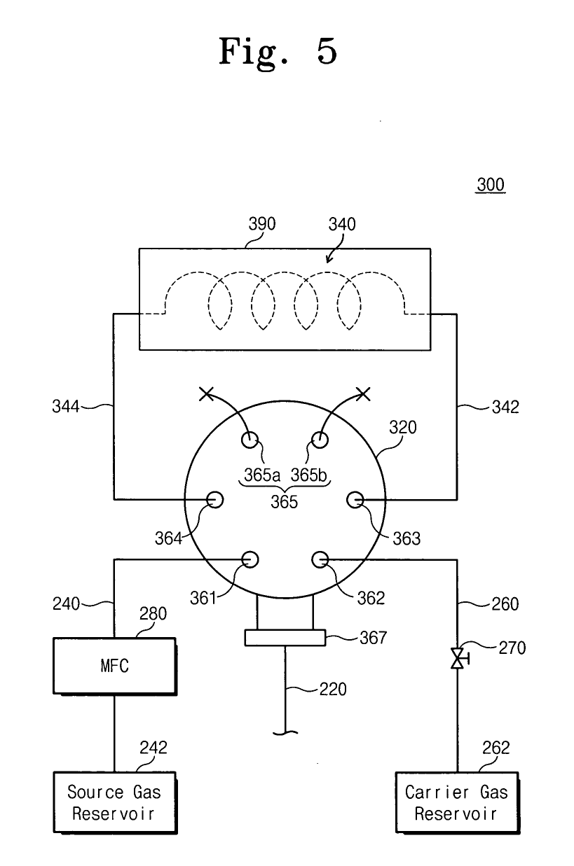

In FIG. 5, “X” indicates that a passage is a blank port that is blocked. A “blank port” refers to a port that is closed. As illustrated, for example, in FIGS. 5 and 9, the blank ports 365a and 365b do not provide an outlet to another chamber or passage. As shown in FIG. 9, passages 391, 392, 393, 394 and 395 are formed in the body 320 and are configured to selectively connect the ports 361, 362, 363, 364, 365 and 367. The controller 380 (FIGS. 6 and 7A-7B) is capable of selectively opening and closing the passages that connect the ports to allow or prevent flow through the passages.

A source supplied from the source supplier 240 can be temporarily stored in the buffer 340. The buffer 340 is placed on the outside of the body 320 and is connected to the ports 363 and 364 of the body 320. In some embodiments, the buffer 340 may be selectively formed in the body 320. As illustrated in FIGS. 4 and 5, the buffer 340 is formed in a coil-shape; however, other configurations can be used. One end of the buffer 340 has an inlet 342 connected to one of the ports 363 of the body 320, and the other end of the buffer 340 has an outlet 344 connected to another one of the ports 364 of the body 320. The volume of the buffer may be sufficiently large so as to be capable of receiving the quantity of the source that is supplied to the chamber 100 in one cycle. The buffer 340 can be releaseably connected to the body 320 so that variously sized buffers can be used according to the desired process conditions. That is, the buffer 340 can be removed from the body 320 and replaced with another buffer of a different size and/or shape so as to provide the capacity to receive the quantity of the source gas needed for different deposition processes and/or conditions. Thus, the volume of the buffer 340, and consequently, the quantity of the source gas provided during one cycle, can be adjusted.

When a source that is disposed in the buffer 340 is gaseous, it may be condensed. To reduce or prevent condensation, a temperature regulator 390 is installed around the buffer 340, and the temperature regulator 390 constantly maintains a temperature of the source disposed in the buffer 340.

FIG. 5 illustrates the ports 361, 362, 363, 364, 365 and 367 formed in the body 320 and the pipes 220, 240, 260, 342 and 344 connected thereto. Referring to FIGS. 4 and 5, the body 320 includes a first supply port 361, a second supply port 362, a first connection port 363, a second connection port 364, a discharge port 367 and at least one blank port 365 (illustrated as blank ports 365a and 365b). The discharge port 367 is configured so as to protrude from the sidewalls of the body 320, and the ports 361, 362, 363, 364 and 365 are conformally placed on an upper surface of the body 320 at regular intervals; however, other positions of the ports 361, 362, 363, 364, 365 and 367 may be used.

As illustrated, the source supplier 240 is connected to the first supply port 361, and the carrier gas supply pipe 260 is connected to the second supply port 361. In addition, the first connection port 363 is connected to the inlet 342, and the second connection port 364 is connected to the outlet 344. The discharge port 367 is connected to the fluid supply pipe 220, and the end of the blank port 365 is closed. The end of the blank port 365 can be selectively opened and may be connected to a recovery pipe (not shown) for recovering fluid flowing through the blank port 365.

As shown in FIG. 9, the plurality of passages 391, 392, 393, 394 and 395 are formed in the body 320. The passage 391 connects the first supply port 361 and the first connection port 363, and the passage 393 connects the first supply port 361 and the blank port 365a so that a source can selectively flow from the source supplier 240 to the blank port 365a or to the inlet 342. The passage 392 connects the second port 362 and the first connection port 363, and the passage 394 connects the second supply port 362 and the blank port 365 so that a carrier gas can selectively flow from the carrier gas supply pipe 260 or to the inlet 342 or to the blank port 365. In addition, the passage 395 connects the second connection port 364 and the discharge port 367 so that a fluid stored in the buffer 340 can flow to the fluid supply pipe 220.

With reference to FIGS. 6 and 7A-7B, the controller 380 controls the flow direction of fluids by selectively opening or blocking the passages 391 and 392. FIG. 6 schematically shows an example of the controller 380; however, other suitable configurations of fluid controllers can be used. Various changes and modifications can be made in order to open/block a passage by which a fluid flows. FIGS. 7A and 7B show that the passage 391 for connecting ports 361, 363 and 365a is opened by operating an actuator 386. Referring to FIG. 7, the controller 380 has a diaphragm 382, a plunger 384, an actuator 386 and a controller (not shown). The diaphragm 382 is arranged so as to block extendible rubber passages 391, 392, 393, 394 and 395. One diaphragm or a plurality of diaphragms may be used. The plunger 384 is combined to the backside of the diaphragm 382 and is driven by the actuator 386. The plungers 384 are respectively placed at the passages 391 and 393 between the ports 361, 363 and 365a. One plunger 384 may be driven by one actuator 386. In some embodiments, as shown in FIG. 6, more than one of the plungers 384 may be simultaneously driven by one actuator 386. The controller controls the actuator 386 in order to open or block the passages 391 and 393 in accordance with a predetermined sequence and/or timing. Referring to FIG. 7A, when the plunger 384a moves downward, the diaphragm 382 is expanded at the passage 391, and the first supply port 361 and the first connection port 363 are connected. Accordingly, the passage 391 is opened, and the source flows to the buffer 340. Referring to FIG. 7B, when the plunger 384a moves upwards, the passage connecting the first supply port 361 and the first connection port 363 is blocked, and when the plunger 384a moves downward, the passage 393 connecting the first supply port 361 and the blank port 365 is opened. As a result, the source flows to the blank port 365a.

FIG. 8 illustrates operations of a pulse fluid supplier 300 so as to cyclically provide a source utilizing a time-sharing process. Whenever the source is provided to the fluid supplier 220 once, the pulse fluid supplier 300 sequentially takes steps including a charge step, a discharge step and a pumping step as shown in FIG. 8. In the charge step, the source is disposed in the buffer 340, and in the discharge step, the source that is disposed in the buffer 340 is discharged to the fluid supplier 220 by a carrier gas. In the pumping step, all residual materials in the buffer 340 are exhausted from the buffer 340. Because the buffer 340 is full of the source at every charge step, and the source is completely discharged to the fluid supply pipe 340, the quantity of the source supplied to the chamber 100 at every cycle is constant. Moreover, since substantially all of the residual fluid in the buffer 340 is pumped out of the buffer after discharging, the quantity of the source disposed in the buffer 340 at the next step is equal to that of a previous cycle.

According to some embodiments, the mass flow controller 250 installed on the source supply pipe 240 and a valve installed on the carrier gas supply pipe 260 are maintained in an opened state during the deposition process. In addition, the passages 391, 392, 393, 394 and 395 for connecting each of the ports 361, 362, 363, 364, 365 and 367 in the pulse fluid supplier 300 can be opened or blocked, thereby controlling whether the fluid is provided or not. FIGS. 9 to 11 illustrate the flow of fluid through the passages 391, 392, 393, 394 and 395 during the charge step, the discharge step and the pumping step, respectively. As illustrated, a blackened valve symbol shown in the passage means that the passages 391, 392, 393, 394 and 395 are blocked, and an un-blackened valve symbol means that the passages 391, 392, 393, 394 and 395 are not blocked.

Referring to FIG. 9, in the charge step, the passage 391 connecting the first supply port 361 and the first connection port 363 is opened, and the passage 393 connecting the first supply port 361 and the blank port 365 is blocked so that the source flows to the buffer 340. In addition, the passage 392 connecting the second supply port 362 and the first connection port 363 is blocked, and the passage 394 connecting the second supply port 362 and the blank port 365 is opened so that the carrier gas flows to the blank port 363. In order to fill the source in the buffer 340, the passage 395 connecting the second connection port 364 and the discharge port 367 is blocked.

If the buffer 340 is full of the source, the discharge step may be performed. Referring to FIG. 10, in the discharge step, the passage connecting the first supply port 361 and the first connection port 363 is blocked, and the passage 393 connecting the first supply port 361 and the blank port 393 is opened so that the source flows to the blank port 365. The passage 392 connecting the second supply port 362 and the first connection port 363 is opened, and the passage 394 connecting the second supply port 362 and the blank port 365 is blocked so that the carrier gas flows to the buffer 340. In order to make the source disposed in the buffer 340 flow to the fluid supply pipe 220 by the carrier gas, the passage connecting the second connection port 364 and the discharge port 367 is opened.

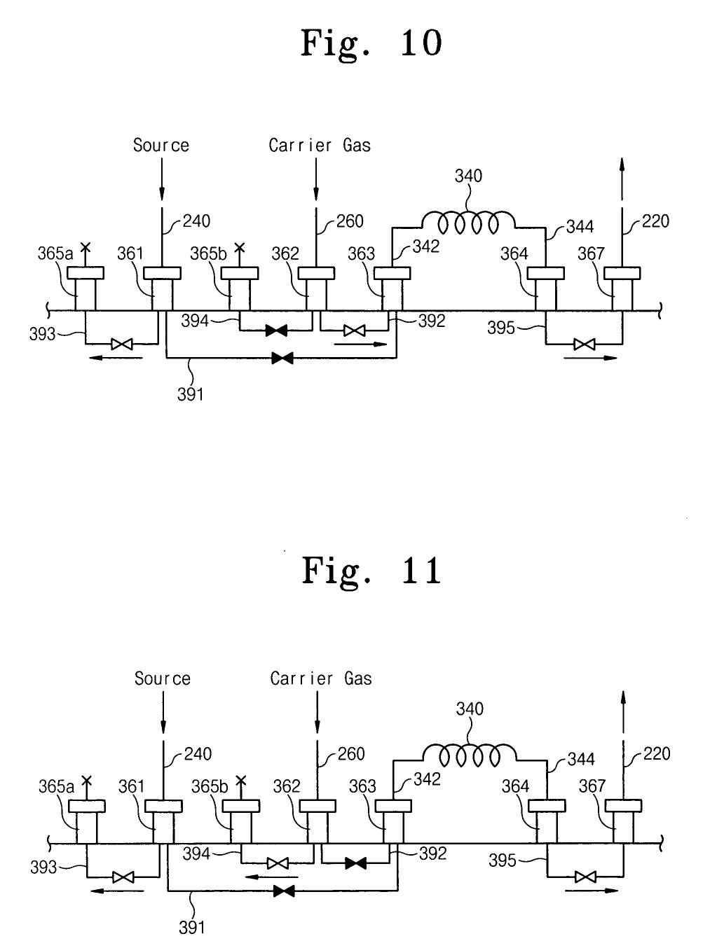

Then, a step of pumping the inside of the buffer 340 is performed. An exhaust pipe 152 with additional pump may be installed on the buffer 340. However, it is preferable that the pumping is performed by a pump 150 installed on the exhaust pipe 152 connected to the chamber 100 (FIGS. 2-3). Referring to FIG. 11, in the pumping step, the passage 391 connecting the first supply port 361 and the first connection port 363 is blocked, and the passage 392 connecting the first supply port 361 and the blank port 365 is opened. The passage 392 connecting the second supply port 362 and the first connection port 363 is blocked, and the passage 392 connecting the second supply port 362 and the blank port 365 is opened. In addition, in order to perform pumping in the buffer 340, the passage 395 connecting the second connection port 364 and the discharge port 367 is opened.

Embodiments of the present invention are described with respect to the body 320, which has at least one blank port 365 (illustrated as blank ports 365a and 365b), and the buffer 340, which is configured so that the source and carrier gas flow to the buffer 340 and/or the blank port 365. However, alternative configurations can be used. For example, the blank port 365 may be omitted from the body 320, and the flow of the source and the carrier gas may be controlled by blocking/opening the passages 391 and 392, which connect the first supply port 361 and the first connection port 363, and the second supply port 362 and the second connection port 364, respectively.

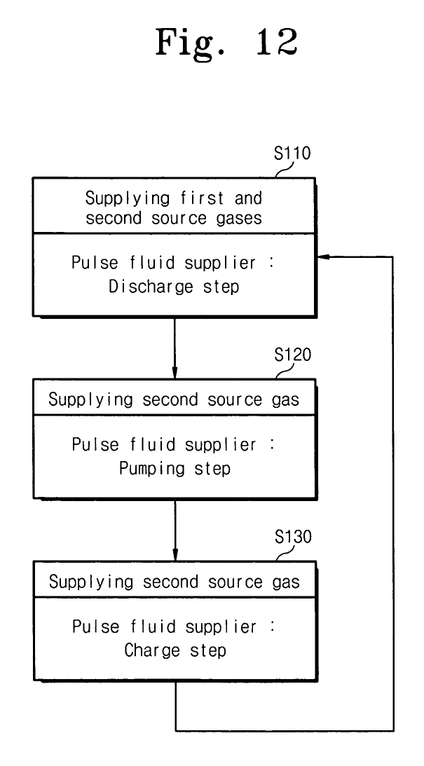

FIG. 12 is a flowchart showing a sequential deposition process by a cyclic chemical vapor deposition method, which may be executed using the above-mentioned apparatus 1. Referring to FIG. 12 and FIGS. 2-3, the wafer is transferred in the chamber 100 to be placed on the substrate support 120. The discharge step described above is performed by the pulse fluid supplier 300, and the first source gas is supplied to the chamber 100. At the same time, the second source gas is supplied to the chamber 100. The first and second source gases chemically react in the chamber, and then a product resulting from the reaction is deposited on the wafer W. The source of the first source gas is supplied to the pulse fluid supplier 300 in a liquid state and is vaporized before inflowing to the chamber (S 110). The pulse fluid supplier 300 performs the pumping step described above, and the residual fluid of the buffer 340 is exhausted so that and only second source gas is supplied to the chamber (S 120) Subsequently, the pulse fluid supplier 300 performs the charge step described above, and the source gas is disposed in the buffer 340, and the second source gas is continuously supplied to the chamber 100. The wafer W is annealed by the second source gas and by-products on the wafer W are removed. These operations are repeated by one cycle including the above three steps until the process is completed.

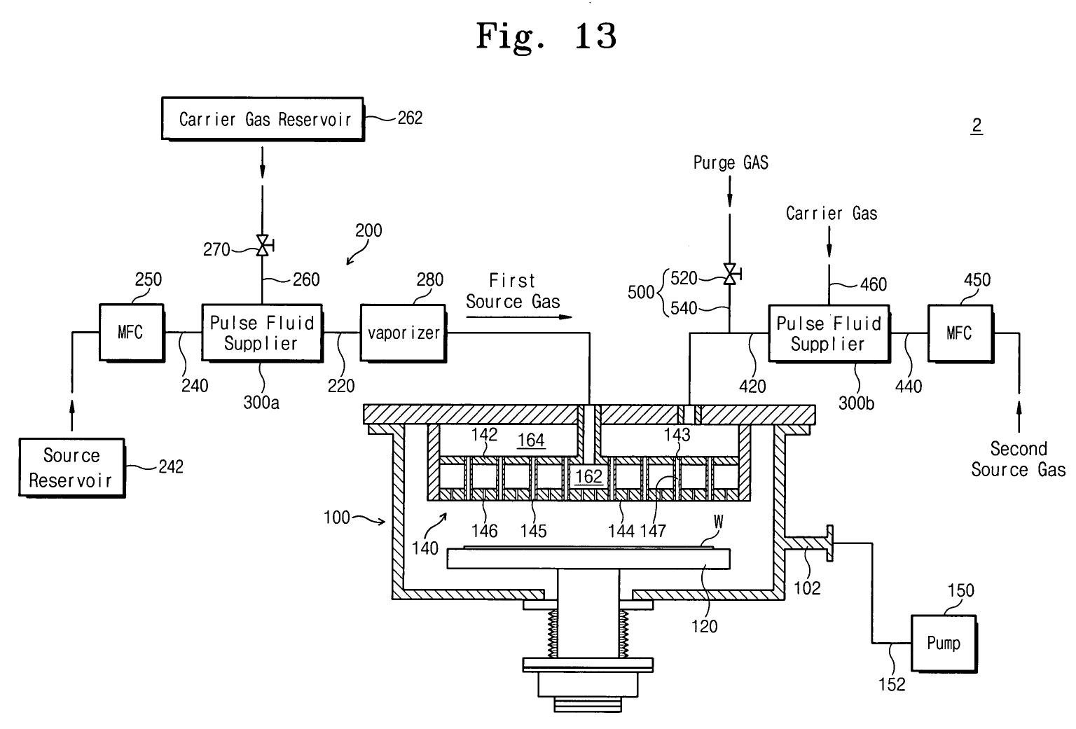

With reference to FIG. 13, an apparatus 2 for performing a deposition process by an atomic layer deposition method using the above-mentioned pulse fluid supplier 300 is illustrated. The deposition apparatus 2 has a chamber 100, a first source gas supply part 200, a second source gas supply part 400 and a purge gas supply part 500. The chamber 100 and the first source gas supply part 200 may be the same as those described with respect to FIG. 2, and can include a first pulse fluid supplier 300a, which can be the same as the pulse fluid supplier 300 described above. The second source gas supply part 400 has a fluid supply pipe 420 and a second pulse fluid supplier 300b. A gaseous second source gas and a carrier gas are supplied to the fluid supply pipe 420. The structure and operation of the second fluid supplier 300b may be the same as those of the pulse fluid supplier 300 described above, and the description thereof is thus omitted. The purge gas supply part 500 provides a purge gas to the chamber 100 and has a supply pipe 540 where a valve 520 is installed off of the fluid supply pipe 420. The purge gas performs a function to purge the inside of the chamber 100. Nitrogen gas N₂ or inert gas may be used as the purge gas.

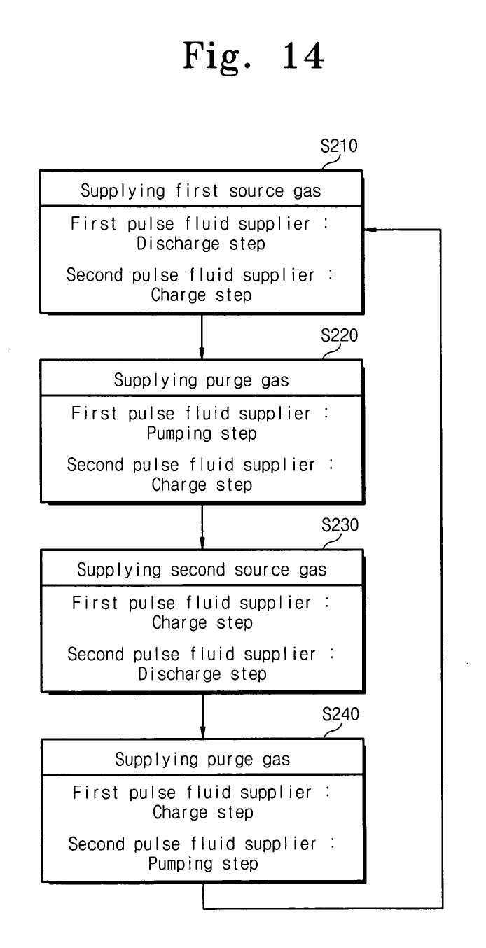

FIG. 14 is a flowchart showing sequential deposition process using the atomic layer deposition method. Referring to FIG. 14, the first source gas is supplied in the chamber 100 to be absorbed on the wafer W. In some embodiments, the purge gas is supplied in the chamber 100 and is not absorbed on the wafer W, but rather the purge gas exhausts the residual first source gas to the outside. Then, the second source gas is supplied in the chamber 100 to react with the first source gas absorbed on a surface of the wafer W so that a film is formed. The purge gas is supplied to the chamber 100 again and exhausts the residual source gases to the outside. Deposition is performed by repeating the above processes.

The discharge step described above is performed in the first pulse fluid supplier 300a of the first source gas supply part. The first source gas supplied in the chamber 100 is absorbed in the wafer W (S210). The purge gas is supplied in the chamber 100 to exhaust the fluid in the chamber 100 to the outside. In this process, the pumping step (described above) is performed by the first pulse fluid supplier 300a. In addition, the charge step is performed by the second pulse fluid supplier 300b of the second source gas supply part 400 during the discharge and pumping steps in the first pulse fluid supplier 300a (S220). Subsequently, then discharge step is performed by the second fluid supplier 300b. The second source gas flows into the chamber 100 and reacts with the first source gas to be absorbed on the wafer W so that a film is formed on the wafer W (S230). The purge gas is supplied to the chamber 100 to exhaust the residual fluid of the chamber 100. In this process, the pumping step is performed by the second pulse fluid supplier 300b. During the discharge and pumping steps in the second pulse fluid supplier 300b, the charge step is performed in the first fluid supplier 300a (S240). These operations are repeatedly performed by one cycle including the above processes until the process is completed.

According to the present invention, it is possible to provide a certain or consistent quantity of a fluid while reducing the fluctuation of flow rate during short cycles when the fluid is cyclically is provided to the chamber.

In the drawings and specification, there have been disclosed embodiments of the invention and, although specific terms are employed, they are used in a generic and descriptive sense only and not for purposes of limitation, the scope of the invention being set forth in the following claims.

1. A deposition apparatus for depositing a predetermined material on a semiconductor substrate, the apparatus comprising:
a pulse fluid supplier comprising:
a buffer configured to provide a space to receive a fluid;
a body including a first supply port configured to connect to a source supplier, a second supply port configured to connect to a carrier gas supply pipe, and a discharge port configured to connect to a fluid supply pipe such that fluid in the buffer flows through the fluid supply pipe to a deposition chamber; and
a controller configured to selectively allow or prevent a source fluid supplied by the first supply port and a carrier gas supplied by the second supply port to flow to/from the buffer, and to allow or prevent a fluid in the buffer to flow to/from the fluid supply pipe.

2. The deposition apparatus of claim 1, wherein the body further comprises:
a first connection port configured to connect to an inlet to the buffer; and
a second connection port configured to connect to an outlet from the buffer.

3. The deposition apparatus of claim 1, wherein the buffer is removeably attached to the body.

4. The deposition apparatus of claim 2, wherein the body further includes at least one blank port, the apparatus further comprising:
a first passage connecting the first supply port and the buffer;
a second passage connecting the second supply port and the blank port, wherein when the first and second passages are opened, the buffer is filled with the source fluid;
a third passage connecting the first supply port to the blank port; and
a fourth passage connecting the second supply port and the first connection port, wherein when the third and fourth passages are opened, the carrier gas is supplied to the buffer.

5. The deposition apparatus of claim 1, wherein the buffer is coil-shaped.

6. The deposition apparatus of claim 1, wherein the controller comprises:
an extendible diaphragm configured to open and close a passage interconnecting two of the ports;
a plunger operatively connected to the diaphragm; and
an actuator configured to open the passage by driving the plunger, wherein when the plunger is moved, a portion of the diaphragm connected to the plunger is extended to open the passage.

7. The deposition apparatus of claim 1, wherein the apparatus further includes a temperature regulator for controlling a temperature of a fluid in the buffer.

8. The deposition apparatus of claim 1, further comprising:
a chamber configured to perform a deposition process; and
a source gas supplier including the pulse fluid supplier and configured to cyclically supply a source of a source gas to the chamber.

9. The deposition apparatus of claim 8, wherein the deposition process is performed using an ALD (Atomic Layer Deposition) process, and wherein the apparatus further comprises:
a second source gas supplier configured to supply a second source gas to the chamber; and
a purge gas supply part configured to supply a purge gas to the chamber.

10. The deposition apparatus of claim 9, wherein the second source gas supplier further includes a pulse fluid supplier configured to cyclically supply the second source gas.

11. The deposition apparatus of claim 8, wherein the deposition process is performed using a cyclic chemical mechanical vapor deposition and the source gas supplier is a first source gas supplier, and wherein the apparatus further includes a second source gas supplier for continuously supplying a second source gas.

12. The deposition apparatus of claim 8, wherein the apparatus is configured to deposit an organic metal on a substrate and the source gas supplier is a first source gas supplier, the apparatus further comprising a second source gas supplier configured to supply a second source gas to the chamber.

13. The deposition apparatus of claim 12, wherein the second source gas supplier is configured to supply a liquid organic metal, and wherein the apparatus further includes a vaporizer connected to the fluid supply pipe to vaporize the liquid organic metal.

14. The deposition apparatus of claim 12, wherein the apparatus further includes a vaporizer connected to the second source gas supplier, and wherein the source is vaporized in the vaporizer and supplied to the buffer.

15. The deposition apparatus of claim 14, wherein the apparatus further includes a temperature regulator configured to control a temperature of a source gas received in the buffer.

16. A method for performing a deposition process, the method comprising:
opening a passage between a source supply and a buffer to fill the buffer with a source fluid;
closing the passage between the source supply and the buffer; and
while the passage between the source supply and the buffer is closed, opening a passage between a carrier gas supply and the buffer and a passage between the buffer and a deposition chamber to supply the deposition chamber with the source fluid.

17. The method of claim 16, wherein, when the passage between the source supply and the buffer is opened, the passage between the carrier gas supply and the buffer and the passage between the buffer and the deposition chamber is closed.

18. The method of claim 16, comprising pumping fluid from the buffer prior to opening the passage between the source supply and the buffer.

19. The method of claim 18, comprising: during the pumping step, closing the passage between the source supply and the buffer, closing the passage between the carrier gas supply and the buffer and opening the passage between the buffer and the deposition chamber.

20. The method of claim 16, wherein the source is a liquid organic metal, the method comprising vaporizing the liquid organic metal before the deposition chamber is supplied with the source fluid.

21. The method of claim 16, wherein the buffer is coil shaped.

22. The method of claim 16, wherein, when the passage between the source supply and the buffer is closed, a passage between the source supply and a blank port is opened.

23. The method of claim 17, wherein, when the passage between the carrier gas supply and the buffer is closed, a passage between the carrier gas supply and a blank port is opened.

24. A method for performing a deposition process, the method comprising:
opening a passage between a first source supply and a first buffer to fill the first buffer with a first source fluid;
closing the passage between the first source supply and the first buffer;
while the passage between the first source supply and the first buffer is closed, opening a passage between a first carrier gas supply and the first buffer and a passage between the first buffer and a deposition chamber to supply the deposition chamber with the first source fluid;
while the passage between the first source supply and the first buffer is closed and the first source fluid is supplied to the deposition chamber, opening a passage between a second source supply and a second buffer to fill the second buffer with a second source fluid;
closing the passage between the second source supply and the second buffer; and
while the passage between the second source supply and the second buffer is closed, opening a passage between a second carrier gas supply and the second buffer and a passage between the second buffer and a deposition chamber to supply the deposition chamber with the second source fluid.

25. A method for performing a deposition process by supplying a first source gas and a second source gas to a chamber, the method comprising the steps of:
providing a pulse fluid supplier that includes a first connection port that provides an inlet to a buffer, a second connection port that provides an outlet from the buffer, a first supply port that receives a source fluid from a source supplier, a second supply port that receives a carrier gas from a carrier gas supplier, and a discharge port that provides fluid to a deposition chamber;
providing a passage connecting the first connection portion and the first supply port;
providing a passage connecting the first connection port and the second supply port,
providing a passage connecting the second connection port and the discharge port;
opening the passage that connects the first connection port and the first supply port to charge the buffer with the source fluid while closing the passage that connects the second supply port to the carrier gas supplier and the passage that connects the second connection port and the discharge port; and
opening the passage that connects the first connection port and the second supply port and the passage that connects the second connection port and the discharge port to discharge the buffer and supply the source fluid to the deposition chamber while closing the passage that connects the first connection-port and the first supply port.

26. The method of claim 25, comprising supplying a second source gas to the deposition chamber.

27. The method of claim 25, further comprising pumping the buffer before charging the buffer with the source fluid.

28. The method of claim 27, wherein the pumping step includes pumping the chamber while closing the passage for connecting the first supply port and the first connection port, closing the passage for connecting the second supply port and the second connection port, and opening the passage for connecting the second connection port and the discharge port.

29. The method of claim 25, wherein the deposition is performed using a cyclic chemical vapor deposition method, and wherein a second source gas is continuously supplied to the deposition chamber while the first source gas is cyclically supplied.

30. The method of claim 25, wherein the source is a liquid organic metal, and wherein the vaporizer for vaporizing the liquid organic metal is installed on a fluid supply pipe that connects the discharge port to the deposition chamber.

31. A method for performing a deposition process by supplying a first source gas and a second source gas to a chamber, the method comprising the steps of:
providing a first pulse fluid supplier connected to a first source fluid and a second pulse fluid supplier connected to a second source fluid, each of the pulse fluid suppliers comprising a first connection port that provides an inlet to a buffer, a second connection port that provides an outlet from the buffer, a first supply port that receives the first source fluid or the second source fluid from a respective first source supplier or second source supplier, a second supply port that receives a carrier gas from a carrier gas supplier, and a discharge port that provides fluid to a deposition chamber;
providing a passage connecting the first connection portion and the first supply port in the first and the second pulse fluid supplier;
providing a passage connecting the first connection port and the second supply port in the first and the second pulse fluid supplier;
providing a passage connecting the second connection port and the discharge port in the first and the second pulse fluid;
discharging the first pulse fluid supplier to supply the first source gas to the deposition chamber while charging the second pulse fluid supplier;
supplying a purge gas to the deposition chamber while pumping the buffer of the first pulse fluid supplier;
discharging the second pulse fluid supplier to supply the second source gas to the deposition chamber while charging the first pulse fluid supplier;
wherein the steps of charging the first or the second pulse fluid supplier comprises:
opening the passage that connects the first connection port and the first supply port to charge the buffer with the first or the second source fluid while closing the passage that connects the second supply port to the carrier gas supplier and the passage that connects the second connection port and the discharge port; and
wherein the steps of discharging the first or the second pulse fluid supplier comprises:
opening the passage that connects the first connection port and the second supply port and the passage that connects the second connection port and the discharge port to discharge the buffer and supply the first or second source fluid to the deposition chamber while closing the passage that connects the first connection port and the first supply port.

32. The method of claim 31, wherein the pumping step is carried out by, in one of the first or the second pulse fluid suppliers, closing the passage for connecting the first supply port and the first connection port, blocking the passage for connecting the second supply port and the second connection port, and opening the passage for connecting the second connection port and the discharge port.
